(19) United States
(12) Patent Application Publication
(10) Pub. No.: US 2020/0313652 A1
(43) Pub. Date: Oct. 1, 2020

(54) RECONFIGURABLE FILTER FOR DIGITALLY CONTROLLED PHASE SHIFTER

(71) Applicant: MobiPhive, Inc., Irvine, CA (US)

(72) Inventors: Stuart Glynn, London (GB); Mohammad Asmani, Ladera Ranch, CA (US)

(21) Appl. No.: 16/833,201

(22) Filed: Mar. 27, 2020

Related U.S. Application Data
(60) Provisional application No. 62/825,248, filed on Mar. 28, 2019.

(51) Int. Cl. H03H 11/04

(52) U.S. Cl. CPC H03H 11/04

(57) ABSTRACT

A reconfigurable filter for a digitally controlled phase shifter has an input port, an output port, and a selectively activatable filter circuit connected to a junction between the input port and the output port. The filter circuit has a first passive element and a second passive element that is selectively and exclusively shunted by activating and deactivating respective active devices to which the first passive element and the second passive element are connected. A high pass characteristic for phase advance or a low pass characteristic for phase delay may be defined.

### CROSS-REFERENCE TO RELATED APPLICATIONS

This application relates to and claims the benefit of U.S. Provisional Application No. 62/825,248 filed Mar. 28, 2019 and entitled “IMPLEMENTATION OF THE LOWER VALUE BITS IN A DIGITALLY CONTROLLED PHASE SHIFTER” the disclosure of which is wholly incorporated by reference in its entirety herein.

### STATEMENT RE: FEDERALLY SPONSORED RESEARCH/DEVELOPMENT

Not Applicable

### BACKGROUND

### 1. Technical Field

The present disclosure relates generally to radio frequency circuits and monolithic microwave integrated circuits (MMICs). More particularly, the present disclosure relates to reconfigurable filters for digitally controlled phase shifters.

### 2. Related Art

A number of recent wireless communications modalities contemplate the use of phased antenna arrays for beam steering purposes. Generally, a series of antennas are arranged in a single or multi-dimensional array. When the antenna array is used to transmit an RF signal, a transmitter circuit feeds the signal to each of the antennas with the phase of the signal as radiated from each of the antennas being varied over the span of the array. To this end, a phase shifter circuit may be incorporated in the RF signal path, with a typical configuration utilizing one phase shifter circuit for each antenna. The collective signal from the individual antennas may have a narrower beam width, and the direction of the beam may be adjusted based upon the constructive and destructive interferences from each antenna transmission resulting from the applied phase shifts.

Both analog and digitally controlled phase shifters are known in the art, though the latter are more common in recent wireless communications applications. Specifically, the degree of phase shift applied by the circuit may be set by a series of digital bits. In an N-bit digitally controlled phase shifter, there may be N cascaded binary weighted phase shifting bits and have a total of 2^{N} possible phase states. The most significant bit (MSB) is typically 180°, and the least significant bit (LSB) will be 360°/2^{N}. Thus, for a 6-bit digitally controlled phase shifter, the least significant bit is 5.625°.

A switched filter architecture is commonly employed in the implementation of the phase shifting bits. In a first switch path, there is a low pass filter that provides a phase delay, and in a second switch path, there is a high pass filter that provides a phase advance. The difference in phase between the low pass state and the high pass state can be made virtually constant over a wide operating frequency band. The nominal phase difference over the band determines the value of the bit, for example, 180°, 90°, 45°, 22.5°, 11.25°, or 5.625°. A typical implementation of the higher value bits involves a configuration in which the low pass filter and the high pass filter are fixed, and a single pole, double throw (SPDT) switch is used to select one or the other. This configuration may also be used for the lower value bits such as for the 22.5°, 11.25°, or 5.625° phase shifts, but such a circuit may have an excessively high insertion loss.

Accordingly, there is a need in the art for a reconfigurable filter for a digitally controlled phase shifter with lower insertion loss as well as low phase and amplitude error.

### BRIEF SUMMARY

The present disclosure contemplates a reconfigurable filter for a digitally controlled phase shifter circuit that improves the performance of the lower value phase shifting bits with respect to insertion loss, phase error, and amplitude error across the operating frequency band. In one embodiment, the filter may include an input port, an output port, and a selectively activatable filter circuit connected to a junction between the input port and the output port. The filter circuit may include a first passive element and a second passive element that is selectively and exclusively shunted by activating and deactivating respective active devices to which the first passive element and the second passive element are connected. Depending on the passive element, there may be a high pass characteristic for phase advance or a low pass characteristic for phase delay.

In another implementation, the reconfigurable filter may include an input port, an output port connected to the input port, and a first passive element connected to a junction between the output port and the input port. There may additionally be a second passive element, along with first and second transistors each connected to the first passive element and to the second passive element with one being exclusively activatable relative to the other. The first transistor may be connected to the junction. The first passive element may be bypassed and the second passive element may be shunted to define a high pass filter when the first transistor is in conductance and the second transistor is out of conductance. The first passive element may be shunted and the second passive element may be shorted out to define a low pass filter when the first transistor is out of conductance and the second transistor is in conductance.

Another embodiment of the present disclosure contemplates a reconfigurable filter for a digitally controlled phase shifter circuit. The filter may include an input port and an output port connected to the input port. There may also be a first transistor that has a first terminal connected to a control voltage input, a second terminal connected to a junction between the input port and the output port, and a third terminal. The filter may include a second transistor with a first terminal connected to a complementary control voltage input, a second terminal connected to ground, and a third terminal connected to the third terminal of the first transistor. There may be a first passive element that may be connected across the first terminal and the third terminal of the first transistor, along with a second passive element that may be connected to ground and to the third terminal of the first transistor and the third terminal of the second transistor.

The present disclosure will be best understood accompanying by reference to the following detailed description when read in conjunction with the drawings.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a schematic diagram of an exemplary first embodiment of a reconfigurable filter of a digitally controlled phase shifter;

FIGS. 2A-2D are graphs showing a simulated performance of the first embodiment of the reconfigurable filter of the present disclosure;

FIG. 3 is a schematic diagram of an exemplary second embodiment of the reconfigurable filter of the digitally controlled phase shifter; and

FIGS. 4A-4D are graphs showing a simulated performance of the second embodiment of the reconfigurable filter of the present disclosure.

### DETAILED DESCRIPTION

The present disclosure encompasses various embodiments of a reconfigurable filter for a digitally controlled phase shifter circuit with performance improvements of the lower value bits. Low insertion loss and low phase and amplitude error are contemplated. The detailed description set forth below in connection with the appended drawings is intended as a description of the several presently contemplated embodiments of the reconfigurable filter and is not intended to represent the only form in which the disclosed invention may be developed or utilized. The description sets forth the functions and features in connection with the illustrated embodiments. It is to be understood, however, that the same or equivalent functions may be accomplished by different embodiments that are also intended to be encompassed within the scope of the present disclosure. It is further understood that the use of relational terms such as first and second and the like are used solely to distinguish one from another entity without necessarily requiring or implying any actual such relationship or order between such entities.

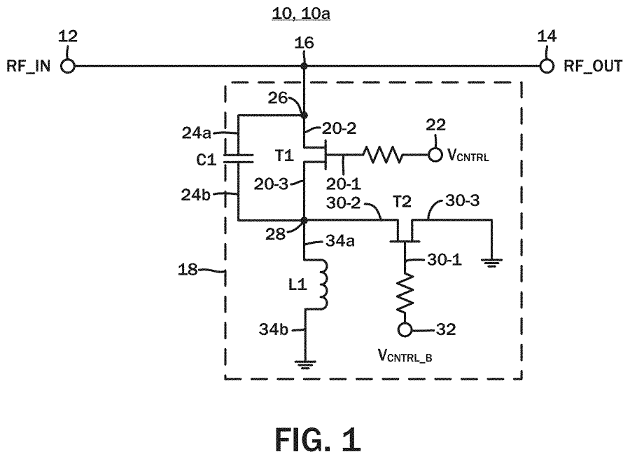

Referring now to the schematic diagram of FIG. 1, a first embodiment of a reconfigurable filter circuit 10a has a radio frequency (RF) signal input port 12 and an RF signal output port 14. The RF signal input port 12 is connected to the RF signal output port, but there is an additional junction 16 to which a filter circuit 18 is connected. It will be appreciated that as referenced in this context, input and output are relative; in some instances, the ports may be reversed in actual function. As will be described in further detail below, the filter circuit 18 may be configured as either an inductor shunt or a capacitor shunt in response to a binary control signal.

The filter circuit 18 has a first transistor T1 as well as a second transistor T2, which in one embodiment are field effect transistors (FET). It will be appreciated that any other suitable transistor configuration may be substituted without departing from the scope of the present disclosure. The first transistor T1 is generally defined by a first terminal 20-1, a second terminal 20-2, and a third terminal 20-3. The first terminal 20-1 may be a gate terminal that is connected to a control voltage input 22, also referenced as V_{CNTRL}. The second terminal 20-2 and the third terminal 20-3 may be either the drain or the source. The second terminal 20-2 is electrically connected to the junction 16. Connected thereto is a first passive element or capacitor C1. Specifically, a first capacitor plate terminal 24a is connected to the second terminal 20-2 of the first transistor T1 at a junction 26 that is electrically contiguous with the junction 16. A second capacitor plate terminal 24b is connected to the third terminal 20-3 of the first transistor T1 at a junction 28. Thus, the first capacitor C1 may be described as being connected across the transistor T1, and specifically across the second and third terminals 20-2 and 20-3 thereof.

The second transistor T2 is likewise defined by a first terminal 30-1, a second terminal 30-2, and a third terminal 30-3. The first terminal 30-1 may be a gate terminal that is connected to a complementary control voltage input 32, which is also referenced as V_{CNTRL_B} and is understood to be the complement of the control voltage input 22. In other words, when the control voltage input 22 has a high value, then the complementary control voltage input 32 has a low value, and vice versa. The second terminal 30-2 is connected to the aforementioned junction 28, which is electrically connected to the second capacitor plate terminal 24b as well as the third terminal 20-3 of the first transistor T1. Also connected to the junction 28 is a second passive element or inductor L1, which is generally defied by a first terminal 34a and a second terminal 34b. More particularly, the first terminal 34a of the inductor L1 is connected to the junction 28, while the second terminal 34b of the inductor L1 is connected to ground.

The embodiments of the present disclosure contemplate the filter circuit 18 being operated such that the first passive element, e.g., the capacitor C1, and the second passive element, e.g., inductor L1, are selectively and exclusively shunted by activating and deactivating the respective active devices, e.g., the first transistor T1 and the second transistor T2, to which such passive elements are connected. Depending on whether the capacitor C1 or the inductor L1 is part of the filter circuit 18 that is connected to the junction between the RF signal input port 12 and the RF signal output port 14, a high pass filter characteristic for phase advance, or a low pass filter for phase delay may be defined. The reconfigurable filter circuit 10 may be particularly suited for implementing the lower value bits of a digitally controlled phase shifter. The specific values of the components utilized, including the capacitor C1 and the inductor L1 may be tuned by those having ordinary skill in the art to achieve the desired phase shifts.

When the transistor T1 is switched on by providing a high voltage to the first terminal 20-1 via the control voltage input 22, the capacitor C1 is bypassed and the first transistor T1 is in conduction (e.g., in the ON state). In the contemplated embodiments of the filter circuit 18, the second transistor T2 is also switched off by providing a low voltage to the first terminal 30-1 via the complementary control voltage input 32. In this state, the second transistor T2 is not in conduction (e.g., in the OFF state). With the capacitor C1 bypassed, the first transistor T1 in conduction while the second transistor T2 is not, the inductor L1 is shunted to ground, and a high-pass filter is defined. As will be recognized by those having ordinary skill in the art, a high pass filter effects a phase advance.

When the first transistor T1 is switched off by providing a low voltage to the first terminal 20-1 via the control voltage input 22, the capacitor C1 is shunted to ground. Furthermore, the second transistor T2 is switched on by providing a high voltage to the first terminal 30-1 via the complementary control voltage input 32, the inductor L1 is shorted out, and the second capacitor plate terminal 24b is tied to ground via the second transistor T2 in conduction. In this configuration, the filter circuit 18 is understood to define a low-pass filter, which effects a phase delay. Although the capacitor C1 and the inductor L1 are configured as illustrated in FIG. 1, it will be recognized that such components may be swapped, that is, the inductor L1 may be connected to the junction 26 and the junction 28, while the capacitor C1 may be connected to the junction 28 and to ground. In such case, the low-pass and high-pass characteristics are understood to be the opposite as described above relative to the input control signals.

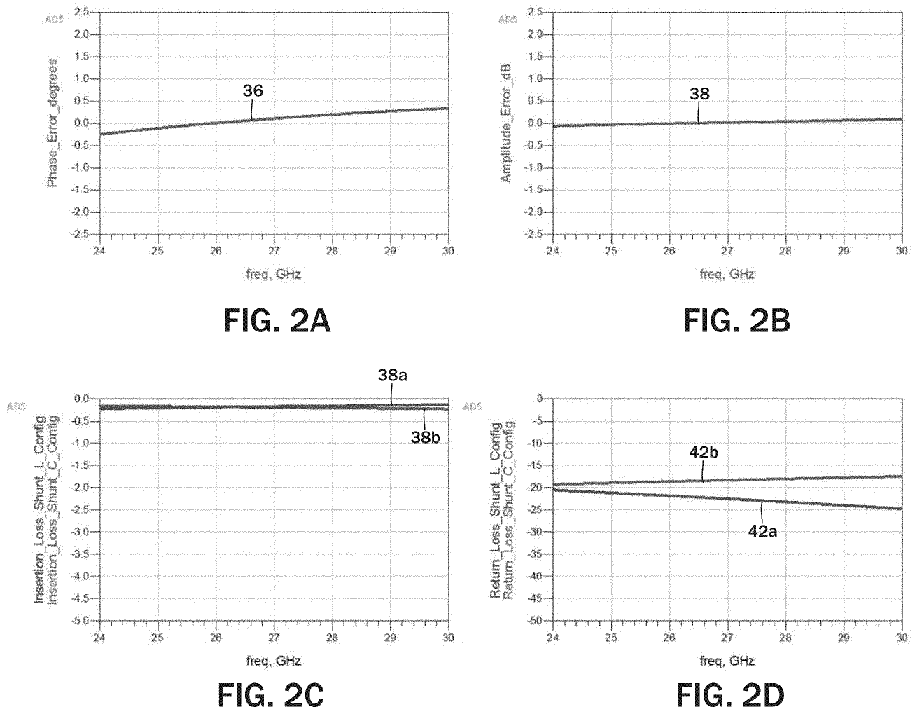

The reconfigurable filter circuit 10 may be utilized in a millimeter wave 5G (5th Generation mobile communications) application with operating frequencies between 24 GHz and 30 GHz. The reconfigurable filter circuit 10 may be fabricated with a complementary metal oxide semiconductor (CMOS) process. With the first embodiment of the reconfigurable filter circuit 10a in particular, it is contemplated for implementing the 11.25° bit, though the least significant bit of 5.625° may also be implemented. The results of the performance simulation of the first embodiment of the reconfigurable filter circuit 10a are shown in the graphs of FIGS. 2A-2D and are specific to the 11.25° bit. FIG. 2A shows a plot 36 of the phase error in degrees over the 24 GHz to 30 GHz operating frequency range, and FIG. 2B shows a plot 38 amplitude error in dB over the same 24 GHz to 30 GHz operating frequency range. Furthermore, the graph of FIG. 2C includes a first plot 40a showing the simulated insertion loss of the first embodiment of the reconfigurable filter circuit 10a with the inductor L1 shunting to ground, along with a second plot 40b showing the simulated insertion loss with the capacitor C1 shunting to ground. Lastly, the graph of FIG. 2D includes a first plot 42a showing the simulated return loss of the first embodiment of the reconfigurable filter circuit 10a with the inductor L1 shunting to ground, and a second plot 42b showing the simulated return loss with the capacitor C1 shunting to ground. The insertion loss and return loss plotted in FIGS. 2C and 2D are in dB.

As illustrated by the foregoing, a very low phase and amplitude error can be achieved along with low insertion loss and good return loss in both the C1 hunting to ground state (low pass filter) and the inductor L1 shunting to ground state (high pass filter). This performance is understood to be possible over conventional configurations because of the lack of a transistor in series with the input and output. Such transistor is understood to have an associated parasitic capacitance when switched off, which is particularly problematic in millimeter wave frequencies.

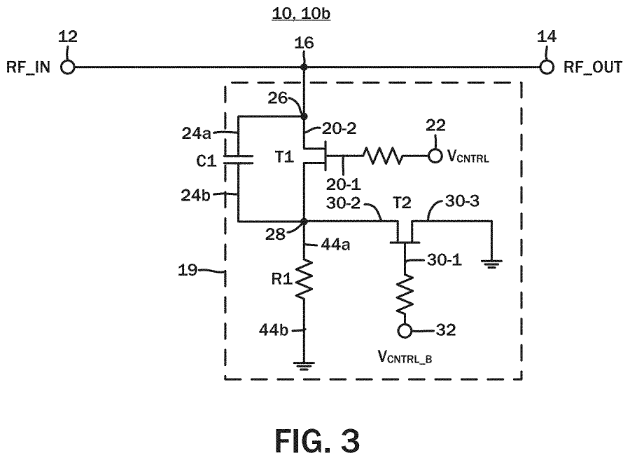

The schematic diagram of FIG. 3 shows a second embodiment of the reconfigurable filter circuit 10b, which includes the same RF signal input port 12 and the RF signal output port 14. Like the first embodiment, the RF signal input port 12 is connected to the RF signal output port, and there is the additional junction 16 to which an alternative configuration of a filter circuit 19 is connected. The filter circuit 19 may be configured as either an resistor shunt or a capacitor shunt in response to a binary control signal.

The filter circuit 19 has a first transistor T1 and a second transistor T2, which again are field effect transistors. The first transistor T1 is generally defined by the first terminal 20-1, the second terminal 20-2, and the third terminal 20-3. The first terminal 20-1 may be a gate terminal that is connected to the control voltage input 22, V_{CNTRL}. The second terminal 20-2 and the third terminal 20-3 may be either the drain or the source of the first transistor T1. The second terminal 20-2 is electrically connected to the junction 16, and further connected thereto is the same first passive element or capacitor C1. The first capacitor plate terminal 24a is connected to the second terminal 20-2 of the first transistor T1 at the junction 26 that is electrically contiguous with the junction 16. The second capacitor plate terminal 24b is connected to the third terminal 20-3 of the first transistor T1 at the junction 28.

The second transistor T2 also includes the first terminal 30-1, the second terminal 30-2, and the third terminal 30-3. The first terminal 30-1 may be a gate terminal that is connected to the complementary control voltage input 32, V_{CNTRL_B}. The second terminal 30-2 is connected to the junction 26, which is electrically connected to the second capacitor plate terminal 24b as well as the third terminal 20-3 of the first transistor T1. Instead of the inductor L1 in the first embodiment, this second embodiment 19 utilizes as the second passive element a resistor R1 with a first terminal 44a and a second terminal 44b. The first terminal 44a of the resistor R1 is connected to the junction 28, and the second terminal 44b is connected to ground.

The foregoing second embodiment of the filter circuit 19 is understood to operate in the same manner as the first embodiment of the filter circuit 18, in which the first passive element, e.g., the capacitor C1, and the second passive element, e.g., the resistor R1, are selectively and exclusively shunted by activating and deactivating the first and second transistors T1 and T2. In the configuration where the capacitor C1 is shunted to ground, there is a low pass filter characteristic, whereas when the resistor R1 is shunted to ground, there is a through-pass characteristic. The resistor R1 is understood to have a large value and may be suitable for the 5.625° lowest value bit.

When the transistor T1 is switched on by providing a high voltage to the first terminal 20-1 via the control voltage input 22, the capacitor C1 is bypassed and the first transistor T1 is in conduction (e.g., in the ON state). The second transistor T2 is also switched off by providing a low voltage to the first terminal 30-1 via the complementary control voltage input 32. In this state, the second transistor T2 is not in conduction (e.g., in the OFF state). With the capacitor C1 bypassed, the first transistor T1 in conduction while the second transistor T2 is not, the resistor R1 is shunted to ground, and a through mode is defined. Although the present disclosure refers to all embodiments having a “high pass” mode and “low pass” mode, in the context of the second embodiment 10b, the “high pass” mode is understood to be the through mode. The term “high pass” is thus intended only as relative to the low pass mode.

When the first transistor T1 is switched off by providing a low voltage to the first terminal 20-1 via the control voltage input 22, the capacitor C1 is shunted to ground. Furthermore, the second transistor T2 is switched on by providing a high voltage to the first terminal 30-1 via the complementary control voltage input 32, the inductor L1 is shorted out, and the second capacitor plate terminal 24b is tied to ground via the second transistor T2 in conduction. In this configuration, the filter circuit 19 is understood to define a low-pass filter that effects a phase delay. Although the capacitor C1 and the resistor R1 are configured as illustrated in FIG. 3, it will be recognized that such components may be swapped, that is, the resistor R1 may be connected to the junction 26 and the junction 28, while the capacitor C1 may be connected to the junction 28 and to ground. In such case, the low-pass and through characteristics are understood to be the opposite as described above relative to the input control signals.

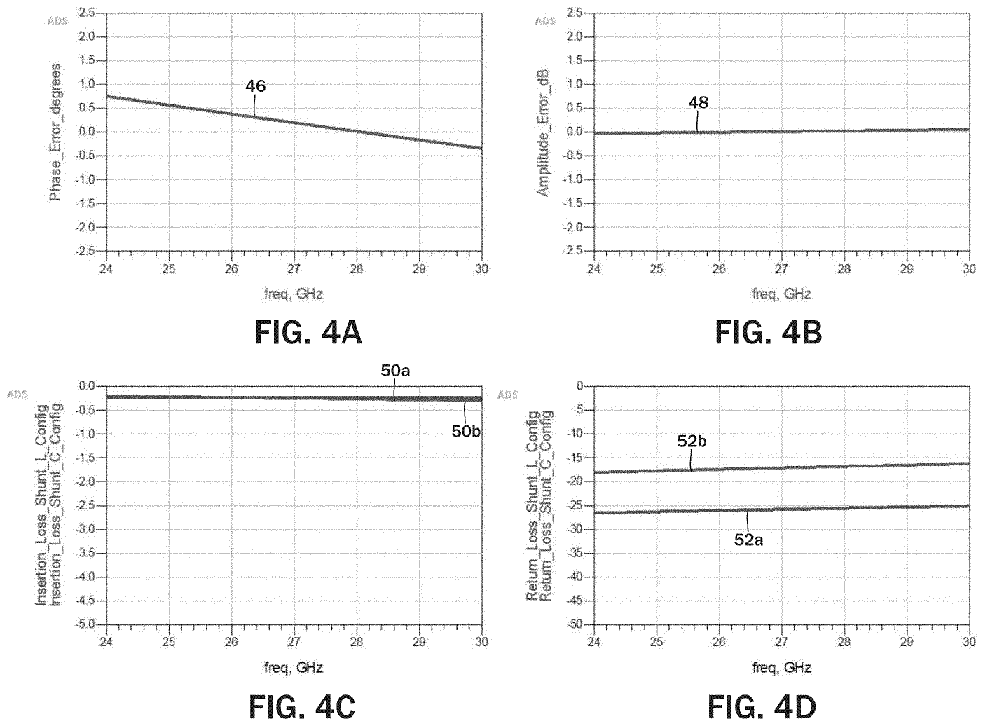

The results of the performance simulation of the second embodiment of the reconfigurable filter circuit 10b are shown in the graphs of FIGS. 4A-4D and are specific to the 5.625° bit. FIG. 4A shows a plot 46 of the phase error in degrees over the 24 GHz to 30 GHz operating frequency range, and FIG. 4B shows a plot 48 amplitude error in dB over the same 24 GHz to 30 GHz operating frequency range. The graph of FIG. 4C includes a first plot 50a showing the simulated insertion loss of the second embodiment of the reconfigurable filter circuit 10b with the resistor R1 shunting to ground, along with a second plot 40b showing the simulated insertion loss with the capacitor C1 shunting to ground. Lastly, the graph of FIG. 4D includes a first plot 52a showing the simulated return loss of the second embodiment of the reconfigurable filter circuit 10b with the resistor R1 shunting to ground, and a second plot 52b showing the simulated return loss with the capacitor C1 shunting to ground. The insertion loss and return loss plotted in FIGS. 4C and 4D are in dB.

The graph of FIG. 4A shows that the phase error over the operating frequency range may be slightly higher compared to the first embodiment of the reconfigurable filter circuit 10a. As discussed above, the second embodiment of the reconfigurable filter circuit 10b does not have a high-pass mode to complement the low-pass mode, but instead has a through mode with a gradual phase change over the operating frequency band. The phase error is nevertheless acceptably low compared to conventional circuits, as the elimination of the in-series transistor results in the elimination of the attendant parasitic capacitances when switched off.

The particulars shown herein are by way of example and for purposes of illustrative discussion of the embodiments of the present disclosure only and are presented in the cause of providing what is believed to be the most useful and readily understood description of the principles and conceptual aspects. In this regard, no attempt is made to show details with more particularity than is necessary, the description taken with the drawings making apparent to those skilled in the art how the several forms of the present disclosure may be embodied in practice.

What is claimed is:

1. A reconfigurable filter for a digitally controlled phase shifter circuit, comprising:
an input port;
an output port; and
a selectively activatable filter circuit connected to a junction between the input port and the output port, the filter circuit including a first passive element and a second passive element being selectively and exclusively shunted by activating and deactivating respective active devices to which the first passive element and the second passive element are connected to define a high pass characteristic for phase advance, and a low pass characteristic for phase delay.

2. The reconfigurable filter of claim 1 wherein the high pass characteristic is activated based upon a control input activating the first active device and a complementary control input deactivating the second active device.

3. The reconfigurable filter of claim 1 wherein the low pass characteristic is activated based upon a control input deactivating the first active device and a complementary control input activating the second active device.

4. The reconfigurable filter of claim 1 wherein the first passive element is bypassed and the second passive element is shunted with the first active element being activated and the second active element being deactivated.

5. The reconfigurable filter of claim 1 wherein the second passive element is bypassed and the first passive element is shunted with the first active element being deactivated and the second active element being activated.

6. The reconfigurable filter of claim 1 wherein the first passive element is a capacitor.

7. The reconfigurable filter of claim 6 wherein the second passive element is an inductor.

8. The reconfigurable filter of claim 7 wherein the selectively activatable filter circuit implements a lower value bit of the digitally controlled phase shifter circuit.

9. The reconfigurable filter of claim 6 wherein the second passive element is a resistor.

10. The reconfigurable filter of claim 9 wherein the selectively activatable filter circuit implements a least significant bit (LSB) of the digitally controlled phase shifter circuit.

11. The reconfigurable filter of claim 1 wherein the active devices are transistors.

12. A reconfigurable filter for a digitally controlled phase shifter circuit, comprising:
an input port;
an output port connected to the input port;
a first passive element connected to a junction between the output port and the input port;
a second passive element; and
first and second transistors each connected to the first passive element and to the second passive element with one being exclusively activatable relative to the other, the first transistor being connected to the junction, the first passive element being bypassed and the second passive element being shunted to define a high pass filter when the first transistor is in conductance and the second transistor is out of conductance, and the first passive element being shunted and the second passive element being shorted out to define a low pass filter when the first transistor is out of conductance and the second transistor is in conductance.

13. The reconfigurable filter of claim 12 wherein the first passive element is a capacitor and the second passive element is an inductor.

14. The reconfigurable filter of claim 13 wherein the high pass filter and the low pass filter implement a lower value bit of the digitally controlled phase shifter circuit.

15. The reconfigurable filter of claim 12 wherein the first passive element is a capacitor and the second passive element is a resistor.

16. The reconfigurable filter of claim 15 wherein the high pass filter and the low pass filter implement a least significant bit of the digitally controlled phase shifter circuit.

17. A reconfigurable filter for a digitally controlled phase shifter circuit, comprising:
an input port;
an output port connected to the input port;
a first transistor having a first terminal connected to a control voltage input, a second terminal connected to a junction between the input port and the output port, and a third terminal;
a second transistor having a first terminal connected to a complementary control voltage input, a second terminal connected to ground, and a third terminal connected to the third terminal of the first transistor;
a first passive element connected across the first terminal and the third terminal of the first transistor; and
a second passive element connected to ground and to the third terminal of the first transistor and the third terminal of the second transistor.

18. The reconfigurable filter of claim 17 wherein the first passive element is a capacitor, and the second passive element is an inductor.

19. The reconfigurable filter of claim 17 wherein the first passive element is a capacitor, and the second passive element is a resistor.
